(19) United States
(12) Patent Application Publication
(10) Pub. No.: US 2026/0026359 A1
(43) Pub. Date: Jan. 22, 2026

(54) IDENTIFICATION MARKING CAVITY FILLING FOR SEMICONDUCTOR PACKAGES

(71) Applicant: Micron Technology, Inc., Boise, ID (US)

(72) Inventors: Hong Wan Ng, Singapore (SG); Ling Pan, Singapore (SG); See Hiong Leow, Singapore (SG); Seng Kim Ye, Singapore (SG); Aik Boo Kelvin Tan, Singapore (SG); Chin Hui Chong, Singapore (SG)

(21) Appl. No.: 19/250,169

(22) Filed: Jun. 26, 2025

Related U.S. Application Data
(60) Provisional application No. 63/673,601, filed on Jul. 19, 2024.

(51) Int. Cl. H01L 23/544; H01L 21/56; H01L 23/31

(52) U.S. Cl. CPC H01L 23/544; H01L 21/56; H01L 23/3157; H01L 2223/54406; H01L 2223/54413; H01L 2223/54433; H01L 2223/54486

(57) ABSTRACT

Methods, systems, and devices for identification marking cavity filling for semiconductor packages are described. A semiconductor device may be formed to be relatively less susceptible to surface failures, including failure initiated by stress risers associated with identification markings. For example, a mold compound material may be formed over one or more semiconductor dies of the semiconductor device. One or more identification markings may be formed in the mold compound material based on forming one or more cavities into a surface of the material. A second material may be formed in the one or more cavities and may fill each of the cavities. The second material may be a crack-resistant material. The second material may be formed through one or more apertures of a stencil, or the second material may be formed by applying the second material over an entirety of the surface of the semiconductor device.

### CROSS REFERENCE

The present application for patent claims priority to U.S. Patent Application No. 63/673,601 by Ng et al., entitled “IDENTIFICATION MARKING CAVITY FILLING FOR SEMICONDUCTOR PACKAGES,” filed Jul. 19, 2024, which is assigned to the assignee hereof, and which is expressly incorporated by reference in its entirety herein.

### TECHNICAL FIELD

The following relates to one or more electronic systems, including identification marking cavity filling for semiconductor packages.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

In some cases, electronic components, including those implemented as memory devices, may experience mechanical stress, thermal stress, or a combination thereof, which may be imposed at least in part on a packaging of the electronic components.

### BRIEF DESCRIPTION OF THE DRAWINGS

FIG. 1 shows an example of a system that supports identification marking cavity filling in accordance with examples as disclosed herein.

FIG. 2 shows examples of devices that support identification marking cavity filling in accordance with examples as disclosed herein.

FIGS. 3A through 3C illustrate examples of operations that support identification marking cavity filling in accordance with examples as disclosed herein.

FIG. 4 shows a flowchart illustrating a method or methods that support identification marking cavity filling for semiconductor packages in accordance with examples as disclosed herein.

### DETAILED DESCRIPTION

Electronic devices, such as semiconductor devices (e.g., memory devices, processing devices), may experience various stresses, such as mechanical stress, thermal stress, electrical stress, or a combination thereof. For example, some evaluation procedures (e.g., reliability testing, stress testing) may apply various stresses to an electronic device (e.g., a semiconductor device, a semiconductor package, semiconductor dies, a chip, or other electronic device) to verify a reliability of the device. Additionally, or alternatively, some electronic devices may experience stresses during operation, such as when installed or implemented in a given implementation. In some cases, applied stress(es) may cause portions of an electronic device to fail (e.g., fracture, yield, deform, weaken), which may resulting in cracking (e.g., ruptures, divisions, discontinuities, slits) of one or more device materials.

In some examples, a material failure of an electronic device may be associated with (e.g., initiated at, located at) one or more identification markings (e.g., text, graphics, barcodes) on a surface of the device. Such identification markings may include one or more identifiers (e.g., unique identifiers for tracking, quality control, and security) that are engraved or etched onto the surface of the device. For instance, forming an identification marking may include forming a cavity (e.g., by a laser, by an etching operation) in a material (e.g., a package covering material, a mold compound material, an epoxy molding compound (EMC)) of the device. In some examples, cavities in a material may be associated with a local stress riser (e.g., stress amplification) that locally weakens the material, and may be relatively more susceptible to failure when a stress (e.g., thermal stress, mechanical stress) is applied. Such material failures in an electronic device may adversely affect performance characteristics (e.g., electrical characteristics, environmental resistance characteristics, corrosion resistance characteristics), reduce mechanical integrity, and degrade a durability of the semiconductor device, among other drawbacks.

In accordance with one or more techniques described herein, various manufacturing procedures may be used to form an electronic device such that the device may be relatively less susceptible to local failure initiation (e.g., due to the formation of identification marks). For example, a mold compound material (e.g., EMC) may be formed over one or more semiconductor dies (e.g., silicon material, device circuitry) of a semiconductor device to provide a protective exterior layer. One or more identification markings may be formed in the mold compound material based on forming one or more cavities into a surface of the material. A second material (e.g., an epoxy material, a gap fill material) may be formed in the one or more cavities and may fill each of the cavities, which may alleviate at least some aspects of stress amplification associated with the formed cavities. The second material may be a crack-resistant material (e.g., based on having a relatively low elastic modulus), enabling the semiconductor device to withstand relatively higher levels of stress during reliability testing (e.g., without failing, without cracking). The second material may be formed in accordance with various techniques including forming the second material through a stencil, or depositing the second material over an entirety of the surface of the mold compound, among other examples. Thus, based on forming the second material within the one or more cavities (e.g., within the one or more identification markings), electronic devices such as semiconductor devices may be manufactured with increased resistance to surface cracking and other effects, resulting in increased device reliability and improved performance, among other benefits.

In addition to applicability in semiconductor packages as described herein, techniques for identification marking cavity filling may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by increasing a reliability of manufactured electronic devices, which may result in reduced electronic waste and extend the life of electronic devices, among other benefits.

Features of the disclosure are illustrated and described in the context of systems and architectures. Features of the disclosure are further illustrated and described in the context of electronic devices and flowcharts.

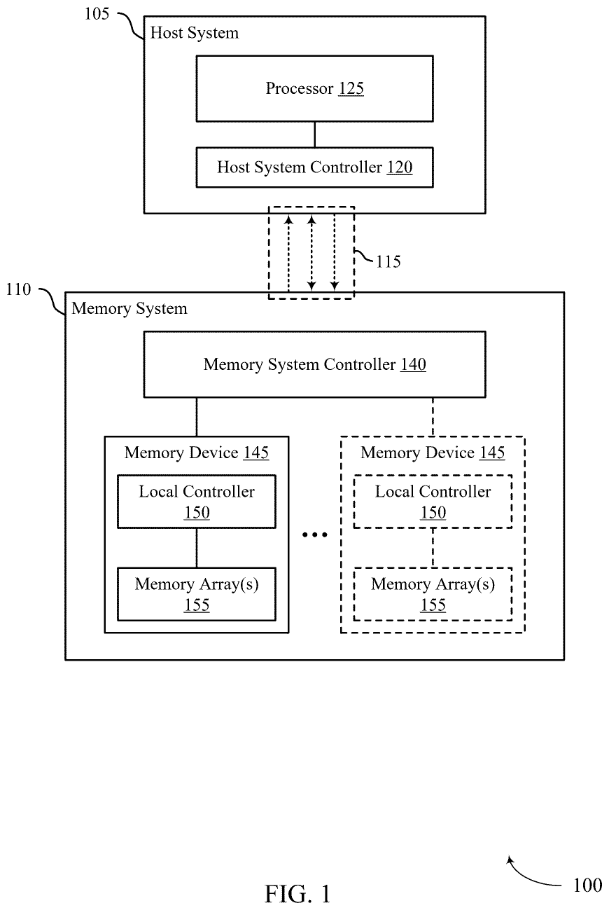

FIG. 1 illustrates an example of a system 100 that supports identification marking cavity filling in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FcRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

In some cases, the system 100, or the components included in the system 100 (e.g., a host system 105, a memory system 110, or other devices therein) may experience various stresses, such as mechanical stresses, thermal stresses, electrical stresses, or a combination thereof (e.g., during evaluation operations, during normal operations). Such applied stresses may cause portions of the system 100 to fail (e.g., fracture, yield, deform, weaken), which may result in cracking (e.g., ruptures, divisions, discontinuities, slits) of one or more components of the system 100. In some cases, a material fracture may be associated with one or more identification markings (e.g., text, graphics, barcodes) created by cavities formed in the surface of a device. The cavities may locally weaken the materials (e.g., may create a local stress riser, may cause a stress amplification) of the system 100 and may be particularly susceptible to failure (e.g., cracking) under stress. Such failure in an electronic device, such as a semiconductor device, may adversely affect performance characteristics, reduce mechanical integrity, and degrade a durability of the system 100, among other drawbacks.

As described herein, various techniques may be used to form an electronic device with increased resistance to failure (e.g., related to identification marking cavities or other stress risers). For example, during fabrication of the system 100 or device therein, a mold compound material (e.g., EMC) may be formed over the device to provide a protective exterior layer. One or more identification markings may then be formed in the mold compound material. For example, cavities associated with the identification markings may be filled with a second material (e.g., an epoxy material, a gap fill material), alleviating at least some aspects of stress amplification associated with the formed cavities. The second material may be a crack-resistant material, enabling the device to withstand relatively higher levels of stress without failing. Thus, based on filling the marking cavities (e.g., laser markings) with a second material, the system 100 and the devices therein may be manufactured with increased resistance to surface cracking and other effects, resulting in increased device reliability and improved performance, among other benefits.

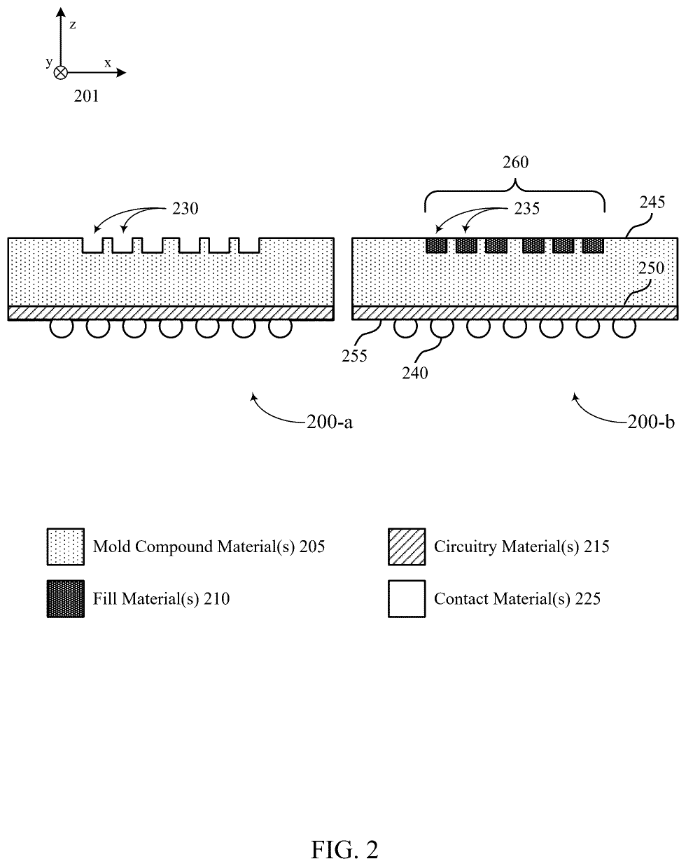

FIG. 2 shows an example of devices 200-a and 200-b (e.g., electronic devices, semiconductor devices) that support identification marking cavity filling in accordance with examples as disclosed herein. The devices 200 are illustrated with cross-sectional views of the devices, which may be described with reference to an x-direction, a y-direction, and a z-direction of the coordinate system 201. The devices 200 may represent examples of various devices and components as described herein, including with reference to FIG. 1. For instance, the devices 200 may be an example of or include a host system 105 (e.g., or one or more components within the host system 105), a memory system 110 (e.g., or one or more within the memory system 110), a semiconductor package (e.g., a high density stacking package), semiconductor dies, a chip, some other electronic device, or any combination thereof.

A device 200 may include (e.g., be manufactured with, constructed with, formed with) various materials such as one or more mold compound materials 205 (e.g., an EMC), one or more circuitry materials 215 (e.g., one or more semiconductor dies, one or more semiconductor substrates, one or more silicon substrates, circuitry silicon, conductive traces, other circuit component materials), and one or more contact materials 225 (e.g., electrical contacts, solder balls, conductive contacts, interface pads, input/output pins). In some cases, mold compound material(s) 205 may be formed over the circuitry material(s) 215 to provide a protective exterior layer for a device 200. The circuitry material(s) 215 may include one or more semiconductor dies, memory array circuitry, processing circuitry, or other circuitry associated with operating the device (e.g., a processor 125, a host system controller 120, a memory system controller 140, a memory device 145, a local controller 150, one or more memory arrays 155).

In some cases, a device 200 may experience various stresses. For example, some evaluation procedures may apply various stresses to verify a reliability of the device 200. For instance, thermal stresses, mechanical stresses, and other tests may be applied to a device 200 to confirm that the device 200 is able to maintain expected operations (e.g., satisfy performance expectations) after experiencing adverse conditions or events (e.g., relatively high or low temperatures, an exerted force, a loading condition, a drop event, tension loading). Additionally, or alternatively, a device 200 may experience stresses during operation, such as when installed or implemented in a given application. In some cases, applied stress(es) may cause portions of a device 200 (e.g., mold compound material(s) 205) to fail (e.g., fracture, yield, deform, weaken), which may resulting in cracking (e.g., ruptures, divisions, discontinuities, slits) of materials of the device 200-a.

In some cases, failure of mold compound material(s) 205 may be associated with (e.g., exaggerated by, caused by, initiated at) a formation of one or more cavities 230. In some examples, cavities 230 may be formed for the purpose of identifying (e.g., uniquely) a device 200, and may be associated with one or more identification markings (e.g., text, graphics, barcodes, or other markings). That is, cavities 230 may form one or more identification markings. An “identification marking” (e.g., such as a laser markings) may include a process of engraving or etching unique identifiers onto a product or component. For example, cavities 230 may be formed via a laser marking process (e.g., laser mark cavities) that removes a portion of mold compound material(s) 205 of a device 200. However, cavities 230 may weaken mold compound material(s) 205 of a device 200. For example, cavities 230 of the device 200-a may be associated with stress risers (e.g., geometric stress risers, surface irregularities, surface cracking, surface weakening, material embrittling) that are relatively more susceptible to local material failure. For instance, when experiencing tension loading the failure may begin at a cavity 230 (e.g., a laser mark line) and may propagate across the materials of the device 200-a. Such cracking in the device 200-a may adversely affect electrical characteristics, reduce mechanical integrity, and degrade durability.

In accordance with one or more techniques described herein, various manufacturing procedures may be used to form the device 200-b with a reduced sensitivity to failure from applied stress. The device 200-b may be an example of a device that is relatively less susceptible to failures (e.g., cracking effects, failure propagation) than the device 200-a. The device 200-b may have one or more mold compound materials 205 (e.g., a first material) formed over a surface 250 of one or more circuitry materials 215 (e.g., in an over-mold implementation, of a planar device). The circuitry material(s) 215 may be associated with (e.g., coupled with, bonded with) one or more contacts 240 (e.g., electrical contacts) formed of one or more contact materials 225 (e.g., copper, aluminum, tungsten). The contact(s) 240 may be formed on a surface 255 of the circuitry material(s) 215 that is opposite the surface 250. The mold compound material(s) 205 may provide electrical isolation, environmental protection, and mechanical support for the device 200-b and the components therein. The circuitry material(s) 215 (e.g., the circuitry, an active layer) of the device 200-b may include one or more semiconductor dies (e.g., a set of dies, one or more stacks of dies) or other electronic components (e.g., capacitors, resistors, transistors, relays, switches, sensors, oscillators). For example, the circuitry material(s) 215 may include one or more semiconductor dies that include processing circuitry, memory array circuitry, or a combination thereof.

In some examples, one or more cavities 230 may be formed in a surface 245 of the device 200-b in order to form (e.g., create, engrave) one or more identification markings 260. To strengthen the surrounding mold compound materials 205 (e.g., to reduce a stress amplification, to reduce a propensity for failure propagation), cavities 230 may be filled with one or more fill materials 210 (e.g., a second material, an epoxy material, a crack-resistant epoxy filling, or other materials), forming one or more filled cavities 235. One or more techniques for filling (e.g., depositing material within) cavities 230 may be supported, such as applying a stencil over the surface 245 (e.g., prior to applying fill material(s) 210) or applying fill material(s) 210 over an entirety of the surface 245.

The one or more filled cavities 235 may form one or more identification markings 260 at a surface 245 of the mold compound material(s) 205. The one or more fill materials 210 may be a different material than the mold compound material(s) 205. For example, mold compound material(s) 205 may be a first epoxy material (e.g., a thermoset) and fill material(s) 210 may be a second type epoxy material different than the first epoxy material (e.g., with a different color, with a different modulus, with a different viscosity). After application, fill material(s) 210 may be planarized (e.g., via chemical-mechanical planarization (CMP) operation, via a grinding operation, via a skimming operation) to be coplanar with mold compound material(s) 205 at the surface 245. Here, “planarize” may refer to a process of making a surface flat or planar, for example, by way of polishing, grinding, etching, cleaning, cutting, or some other planarizing technique.

In some examples, mold compound material(s) 205 may be associated with a different color than the fill material(s) 210 (e.g., based on a different chemical composition of the respective materials, to support visual identification). The mold compound material(s) 205 and fill material(s) 210 may include respective organic (e.g., carbon-based) materials. In some examples, fill material(s) 210 may be associated with a relatively lower viscosity than mold compound material(s) 205 (e.g., during application or deposition of the material). For example, a relatively low viscosity may facilitate fill material 210 filling cavities 230, scaling cracks, or bonding with surfaces of cavities 230, among other benefits.

In some examples, mold compound material(s) 205 may be associated with a first modulus of elasticity and fill material(s) 210 may be associated with a second modulus of elasticity that is less than the first modulus of elasticity (e.g., after a curing process). A “modulus of elasticity” (e.g., an elastic modulus) may refer to a measure of a material's stiffness or resistance to deformation. For example, if a material has a relatively high elastic modulus, it may not easily deform when force or stress is applied (e.g., may be relatively stiff). Conversely, a material with a relatively low elastic modulus may be relatively more flexible and may deform more easily under stress (e.g., may be relatively compliant). An clastic modulus may be measured in Pascals (Pa) or Gigapascals (GPa). In some examples, fill material(s) 210 may have a modulus of elasticity that is more than fifty percent lower than the elastic modulus of the mold compound material(s) 205. In another example, fill material(s) 210 may have a modulus of elasticity that is at least an order of magnitude less than the elastic modulus of mold compound material(s) 205. A relatively lower modulus of fill material(s) 210 may allow surrounding mold compound material(s) 205 to withstand a relatively greater level of stress (e.g., without failure, without crack propagation).

In some examples, identification marking(s) 260 may be formed after a full package assembly, providing identification information unique to the package or the product type. Identification information may include serial numbers, product codes, or other information that helps track and identify the device 200-b (e.g., for quality control or security purposes). Identification marking(s) 260 may include a text marking, a graphic marking, a barcode marking, other identifying markings, or a combination thereof. Such markings may indicate information associated with the device 200-b such as a product identifier, a device-specific identifier, device specifications, or other information. Identification marking(s) 260 may be formed opposite a surface 255 where contact(s) 240 (e.g., solder balls, pin-outs, interface pads) may be formed. That is, contact(s) 240 may be formed at the surface 255 of the device 200-b and may be coupled with circuitry of the circuitry materials 215 (e.g., one or more semiconductor dies of the device 200-b), and the surface 255 may be opposite the surface 245 (e.g., and the surface 250). In some examples, the surface 255 and the contact(s) 240 may be associated with mounting to or interfacing with other semiconductor packages, devices, dies, or other electronic devices.

In some examples, filling of cavities 230 with fill material(s) 210 (e.g., applying an epoxy fill) may be performed after one or more performance evaluations are completed and after the device 200-b has been marked (e.g., with the one or more identification markings 260). Thus, based on forming fill material(s) 210 within one or more cavities 230, the device 200-b may be manufactured with an increased resistance to failure. For example, the fill material(s) 210 may mitigate (e.g., or prevent) crack propagation when mold compound material(s) 205 (e.g., an EMC) experience an applied stress (e.g., tension loading, a thermal event). Accordingly, by using one or more techniques described herein, devices 200 may be manufactured with increased reliability, improved performance, and longer device lifespan, among other benefits.

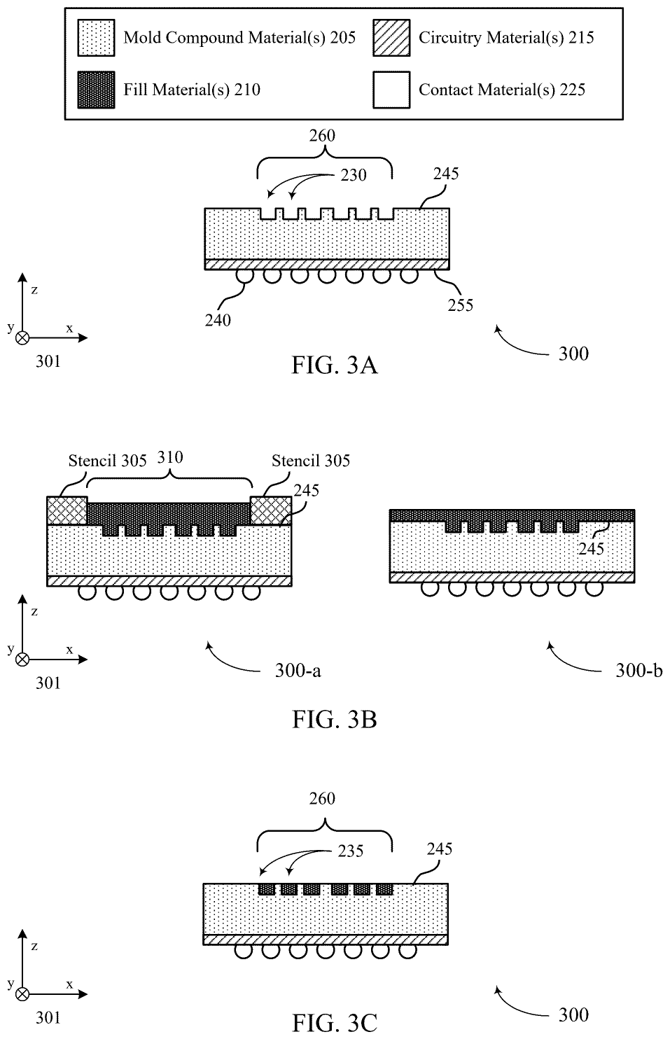

FIGS. 3A through 3C illustrate examples of operations that support identification marking cavity filling in accordance with examples as disclosed herein. Operations are illustrated with reference to a device 300 (e.g., an electronic device, a semiconductor device, a host system 105 or a portion thereof, a memory system 110 or a portion thereof, a device 200, a high density stack package, or some other electronic device). For example, FIGS. 3A through 3C may illustrate aspects of a sequence of operations that may support manufacturing a system 100, a portion thereof, or some other device. Each of the figures may be described with reference to an x-direction, a y-direction, and a z-direction of the coordinate system 301. Operations illustrated in and described with reference to FIGS. 3A through 3C may be performed by a manufacturing system, such as a semiconductor fabrication system configured to perform additive operations (e.g., deposition, epitaxy, bonding), subtractive operations (e.g., etching, trenching, planarizing, polishing, grinding, scraping), modifying operations (e.g., oxidizing, doping, reacting, converting), and supporting operations (e.g., masking, patterning, photolithography, aligning), among other operations that support the described techniques. In some examples, portions of the device 300 that are illustrated with a same pattern may be formed of same or similar materials and portions that are illustrated with different patterns may be formed of different materials.

FIG. 3A shows an example of a cross-sectional view of the device 300 after a first set of one or more fabrication operations that support identification marking cavity filling in accordance with examples as disclosed herein. For example, the first operations may include forming one or more mold compound materials 205 (e.g., EMC, a thermoset material) over one or more one or more circuitry materials 215. The circuitry material(s) 215 may include one or more semiconductor dies of the device 300. The operations may further include forming one or more identification markings 260 at a surface 245 of the mold compound material(s) 205. The identification marking(s) 260 may be based on forming one or more cavities 230 into the surface 245. In some examples, identification marking(s) 260 may include a text marking, a numeric marking, a graphic marking, a barcode marking, or a combination thereof.

Cavities 230 may be formed (e.g., cut, etched, trenched) based on applying a laser to the surface 245 of the mold compound material(s) 205, or based on some other material removal technique. As illustrated, the device 300 includes six cavities 230, however, any quantity of cavities 230 may be formed in a device 300, including more or fewer cavities 230 than shown. In some examples, a lateral edge of the one or more mold compound materials 205 may be coplanar with a lateral edge of the circuitry material(s) 215 (e.g., may terminate at a same point along the x-axis). In some examples, mold compound material(s) 205 may have a greater thickness (e.g., along the z-direction) than circuitry material(s) 215.

In some examples, the first set of operations may include forming one or more contacts 240 at a surface 255 of the device 300. Contact(s) 240 may be formed of one or more conductive materials (e.g., solder, copper, aluminum, tungsten, other metallic materials, or a combination thereof). The contact(s) 240 may be coupled with circuitry of one or more semiconductor dies (e.g., circuitry included in the circuitry material(s) 215). In some examples, the surface 245 of the mold compound material(s) 205 may be opposite the surface 255. That is, the surface 245 may be opposite a surface 255 that includes contact(s) 240, which may be coupled with the circuitry of the one or more semiconductor dies of the device 300. In some examples, semiconductor dies of the circuitry material(s) 215 may include processing circuitry, memory array circuitry, other circuitry, or a combination thereof.

FIG. 3B show examples of cross-sectional views of the device 300 after respective second sets of one or more fabrication operations (e.g., as a device 300-a and a device 300-b, respectively) that support identification marking cavity filling in accordance with examples as disclosed herein. For example, a second set of operations may include forming one or more fill materials 210 (e.g., a second material, and epoxy material, a crack resistant epoxy material), different than the mold compound material(s) 205, in the one or more cavities 230.

In some examples, forming the one or more fill materials 210 may be formed based on using a stencil 305 (e.g., to direct a formation of the fill material(s) 210 over cavities 230). An example of such techniques may be illustrated by the device 300-a (e.g., a stencil printing example). In such examples, a stencil 305 may be applied to the surface 245, which may cover a portion of the surface 245 and may leave the one or more cavities 230 (e.g., and potentially relatively small portions of the surface 245) exposed through one or more apertures 310 of the stencil 305. Aperture(s) 310 of the stencil 305 may be aligned with cavities 230, and fill material(s) 210 may be formed through the aperture(s) 310. In some examples, fill material(s) 210 may be applied over the stencil 305, and a tool (e.g., a skimming tool) may be used to spread the fill material(s) 210 to fill each aperture 310. In some examples, by using the stencil 305 to form the fill material(s) 210, a manufacturing system may increase a units per hour of manufacturing, thus increasing a speed of production.

Additionally, or alternatively, fill material(s) 210 may be formed based on depositing the fill material(s) 210 directly over the surface 245 (e.g., without a stencil 305). An example of such techniques may be illustrated by the example device 300-b (e.g., an ink coating example). In such examples, fill material(s) 210 may be deposited (e.g., and spread) over an entirety of the surface 245 (e.g., extending to each lateral edge of the mold compound material(s) 205). In some examples, a tool may be used to spread the fill material(s) 210 and ensure that each of the one or more cavities 230 is filled. The fill material(s) 210 may prevent failures such as crack propagation (e.g., when an EMC experiences tension loading).

FIG. 3C shows an example of a cross-sectional view of the device 300 after third set of one or more fabrication operations that support identification marking cavity filling in accordance with examples as disclosed herein. For example, the third set of operations may include removing (e.g., after forming the fill material(s) 210 in the one or more cavities 230) an excess portion of the fill material(s) 210 formed outside the one or more cavities 230. An excess portion may include any portion of the fill material(s) 210 that is formed outside a cavity 230 (e.g., fill material(s) 210 remaining on the surface 245 and not in a cavity 230). In some examples, an excess portion of fill material(s) 210 may be removed based on planarizing (e.g., via a CMP process, polishing, grinding) the surface 245 after forming the fill material(s) 210 in the one or more cavities 230, which may include removing surface portions of the mold compound material(s) 205 (e.g., reducing an overall thickness along the z-direction). Additionally, or alternatively, a cleaning operation may be performed to remove any excess material or debris from the surface 245. Based on planarization or cleaning operations, the fill material(s) 210 (e.g., formed in the one or more cavities 230) may be coplanar with the mold compound material(s) 205 (e.g., at the surface 245, at or below a surface in which cavities 230 are formed). In some examples, mold compound material(s) 205 and fill material(s) 210 may be different colors (e.g., based on being different types of epoxy materials). That is, at least a mold compound material 205 at the surface 245 may be associated with a first color, and at least a fill material 210 at the surface 245 may be associated with a second color different than the first color.

Accordingly, identification marking(s) 260 may be formed based on one or more filled cavities 235 (e.g., cavities 230 filled with fill material(s) 210). That is, based on forming the fill material(s) 210, identification marking(s) 260 may be formed with increased tolerance for material deformation, temperature fluctuations, and other stresses. As such, a device 300 may be manufactured with increased resistance to cracking and other breakage, thus resulting in increased reliability, increased device lifespan, and reduced electronic waste, among other benefits.

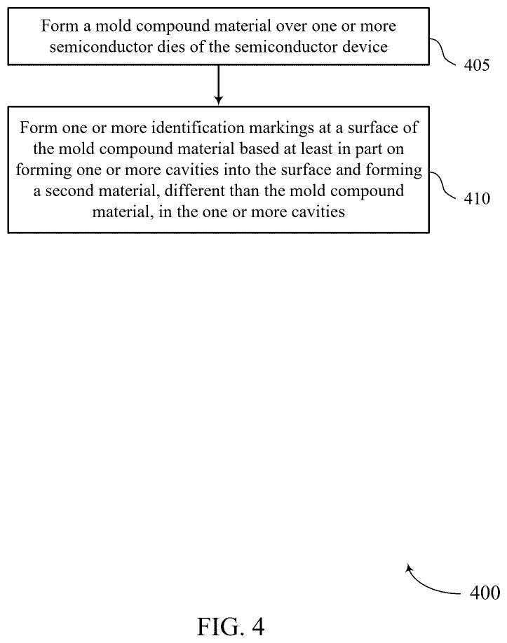

FIG. 4 shows a flowchart illustrating a method or methods 400 that support identification marking cavity filling for semiconductor packages in accordance with examples as disclosed herein. Operations of the method 400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include forming a mold compound material over one or more semiconductor dies of the semiconductor device.

At 410, the method may include forming one or more identification markings at a surface of the mold compound material based at least in part on forming one or more cavities into the surface and forming a second material, different than the mold compound material, in the one or more cavities.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a mold compound material over one or more semiconductor dies of the semiconductor device and forming one or more identification markings at a surface of the mold compound material based at least in part on forming one or more cavities into the surface and forming a second material, different than the mold compound material, in the one or more cavities.

Aspect 2: The method or apparatus of aspect 1, where the one or more identification markings include a text marking, a numeric marking, a graphic marking, a barcode marking, or a combination thereof.

Aspect 3: The method or apparatus of any of aspects 1 through 2, where forming the one or more cavities includes operations, features, circuitry, logic, means, or instructions, or any combination thereof for applying a laser to the surface of the mold compound material.

Aspect 4: The method or apparatus of any of aspects 1 through 3, where forming the second material includes operations, features, circuitry, logic, means, or instructions, or any combination thereof for forming the second material through one or more apertures of a stencil that covers the surface of the mold compound material, the one or more apertures aligned with the one or more cavities.

Aspect 5: The method or apparatus of any of aspects 1 through 4, where forming the second material includes operations, features, circuitry, logic, means, or instructions, or any combination thereof for depositing the second material over an entirety of the surface of the mold compound material.

Aspect 6: The method or apparatus of any of aspects 1 through 5, further including operations, features, circuitry, logic, means, or instructions, or any combination thereof for removing, after forming the second material in the one or more cavities, an excess portion of the second material formed outside of the one or more cavities.

Aspect 7: The method or apparatus of any of aspects 1 through 6, further including operations, features, circuitry, logic, means, or instructions, or any combination thereof for planarizing the surface after forming the second material in the one or more cavities such that the second material is coplanar with the mold compound material.

Aspect 8: The method or apparatus of any of aspects 1 through 7, where the mold compound material is associated with a first modulus of elasticity and the second material is associated with a second modulus of elasticity that is less than the first modulus of elasticity.

Aspect 9: The method or apparatus of aspect 8, where the second modulus of elasticity is more than fifty percent lower than the first modulus of elasticity.

Aspect 10: The method or apparatus of any of aspects 8 through 9, where the second modulus of elasticity is at least an order of magnitude less than the first modulus of elasticity.

Aspect 11: The method or apparatus of any of aspects 1 through 10, where the mold compound material is associated with a first color and the second material is associated with a second color different than the first color.

Aspect 12: The method or apparatus of any of aspects 1 through 11, where the surface of the mold compound material is opposite a second surface of the semiconductor device including one or more electrical contacts coupled with circuitry of the one or more semiconductor dies.

Aspect 13: The method or apparatus of any of aspects 1 through 12, where the one or more semiconductor dies include processing circuitry, memory array circuitry, or a combination thereof.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 14: A semiconductor device, including: one or more semiconductor dies; a mold compound material formed over the one or more semiconductor dies; and one or more identification markings at a surface of the mold compound material, the one or more identification markings including a second material, different than the mold compound material, formed into the surface of the mold compound material.

Aspect 15: The semiconductor device of aspect 14, where the one or more identification markings include a text marking, a graphic marking, a barcode marking, or a combination thereof.

Aspect 16: The semiconductor device of any of aspects 14 through 15, where the second material is coplanar with the mold compound material at the surface.

Aspect 17: The semiconductor device of any of aspects 14 through 16, where the mold compound material is associated with a first modulus of elasticity and the second material is associated with a second modulus of elasticity that is less than the first modulus of elasticity.

Aspect 18: The semiconductor device of aspect 17, where the second modulus of elasticity is more than fifty percent lower than the first modulus of elasticity.

Aspect 19: The semiconductor device of any of aspects 17 through 18, where the second modulus of elasticity is at least an order of magnitude less than the first modulus of elasticity.

Aspect 20: The semiconductor device of any of aspects 14 through 19, where the mold compound material is associated with a first color and the second material is associated with a second color different than the first color.

Aspect 21: The semiconductor device of any of aspects 14 through 20, further including: one or more electrical contacts at a second surface of the semiconductor device and coupled with circuitry of the one or more semiconductor dies, where the surface of the mold compound material is opposite the second surface.

Aspect 22: The semiconductor device of any of aspects 14 through 21, where the one or more semiconductor dies include processing circuitry, memory array circuitry, or a combination thereof.

An apparatus is described. The following provides an overview of aspects of the apparatus as described herein:

Aspect 23: A semiconductor device formed by a process including: forming a mold compound material over one or more semiconductor dies of the semiconductor device; and forming one or more identification markings at a surface of the mold compound material based at least in part on forming one or more cavities into the surface and forming a second material, different than the mold compound material, in the one or more cavities.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
one or more semiconductor dies;
a mold compound material formed over the one or more semiconductor dies; and
one or more identification markings at a surface of the mold compound material, the one or more identification markings comprising a second material, different than the mold compound material, formed into the surface of the mold compound material.

2. The semiconductor device of claim 1, wherein the one or more identification markings comprise a text marking, a graphic marking, a barcode marking, or a combination thereof.

3. The semiconductor device of claim 1, wherein the second material is coplanar with the mold compound material at the surface.

4. The semiconductor device of claim 1, wherein the mold compound material is associated with a first modulus of elasticity and the second material is associated with a second modulus of elasticity that is less than the first modulus of elasticity.

5. The semiconductor device of claim 4, wherein the second modulus of elasticity is more than fifty percent lower than the first modulus of elasticity.

6. The semiconductor device of claim 4, wherein the second modulus of elasticity is at least an order of magnitude less than the first modulus of elasticity.

7. The semiconductor device of claim 1, wherein the mold compound material is associated with a first color and the second material is associated with a second color different than the first color.

8. The semiconductor device of claim 1, further comprising:
one or more electrical contacts at a second surface of the semiconductor device and coupled with circuitry of the one or more semiconductor dies, wherein the surface of the mold compound material is opposite the second surface.

9. The semiconductor device of claim 1, wherein the one or more semiconductor dies comprise processing circuitry, memory array circuitry, or a combination thereof.

10. A method of manufacturing a semiconductor device, comprising:
forming a mold compound material over one or more semiconductor dies of the semiconductor device; and
forming one or more identification markings at a surface of the mold compound material based at least in part on forming one or more cavities into the surface and forming a second material, different than the mold compound material, in the one or more cavities.

11. The method of claim 10, wherein the one or more identification markings comprise a text marking, a numeric marking, a graphic marking, a barcode marking, or a combination thereof.

12. The method of claim 10, wherein forming the one or more cavities comprises:
applying a laser to the surface of the mold compound material.

13. The method of claim 10, wherein forming the second material comprises:
forming the second material through one or more apertures of a stencil that covers the surface of the mold compound material, the one or more apertures aligned with the one or more cavities.

14. The method of claim 10, wherein forming the second material comprises:
depositing the second material over an entirety of the surface of the mold compound material.

15. The method of claim 10, further comprising:
removing, after forming the second material in the one or more cavities, an excess portion of the second material formed outside of the one or more cavities.

16. The method of claim 10, further comprising:
planarizing the surface after forming the second material in the one or more cavities such that the second material is coplanar with the mold compound material.

17. The method of claim 10, wherein the mold compound material is associated with a first modulus of elasticity and the second material is associated with a second modulus of elasticity that is less than the first modulus of elasticity.

18. The method of claim 17, wherein the second modulus of elasticity is more than fifty percent lower than the first modulus of elasticity.

19. The method of claim 17, wherein the second modulus of elasticity is at least an order of magnitude less than the first modulus of elasticity.

20. The method of claim 10, wherein the mold compound material is associated with a first color and the second material is associated with a second color different than the first color.

21. The method of claim 10, wherein the surface of the mold compound material is opposite a second surface of the semiconductor device comprising one or more electrical contacts coupled with circuitry of the one or more semiconductor dies.

22. The method of claim 10, wherein the one or more semiconductor dies comprise processing circuitry, memory array circuitry, or a combination thereof.

23. A semiconductor device formed by a process comprising:
forming a mold compound material over one or more semiconductor dies of the semiconductor device; and
forming one or more identification markings at a surface of the mold compound material based at least in part on forming one or more cavities into the surface and forming a second material, different than the mold compound material, in the one or more cavities.
